(19) United States
(12) Patent Application Publication
(10) Pub. No.: US 2008/0132042 A1
(43) Pub. Date: Jun. 5, 2008

(54) Process For Cleaning Chamber In Chemical Vapor Deposition Apparatus

(75) Inventors: Xiaobo Li, Shanghai (CN); Xia Li, Shanghai (CN); Jie Zhao, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: SEMICONDUCTOR MANUFACTURING INTERNATIONAL (Shanghai) CORPORATION, Shanghai (CN)

(21) Appl. No.: 11/618,696

(22) Filed: Dec. 29, 2006

(30) Foreign Application Priority Data
Dec. 4, 2006 (CN) 200610119063.4

(51) Int. Cl. H01L 21/205

(52) U.S. Cl. 438/488; 257/E21.102

(57) ABSTRACT

A process for cleaning a chamber in a Chemical Vapor Deposition apparatus includes removing a polysilicon layer formed on the interior of the chamber after a doped polysilicon layer has been deposited on a wafer through Chemical Vapor Deposition, and depositing a doped polysilicon layer on the interior of the chamber. With such a process, enough doped ions can be absorbed by the interior of the chamber, and ions doped in a process of depositing a doped polysilicon layer on a surface of a wafer can be prevented from being absorbed on the inner walls of the chamber and the other components in the chamber, resulting in stable doped constituents and resistance value of the doped polysilicon layer deposited on the surface of the wafer.

This application claims the priority of Chinese Patent Application No. 200610119063.4, filed Dec. 4, 2006, the entire disclosure of which is incorporated herein by reference.

### FIELD OF THE INVENTION

The present invention relates to the technical field of semiconductor fabrication, and in particular to a process for cleaning a chamber in a polysilicon deposition process using a Chemical Vapor Deposition method.

### BACKGROUND OF THE INVENTION

In a semiconductor fabrication process, in order to fabricate discrete devices and integrated circuits, various thin films need to be deposited on a wafer substrate, where Chemical Vapor Deposition (CVD) is a commonly used method. The Chemical Vapor Deposition method includes Low-Pressure Chemical Vapor Deposition, High-Pressure Chemical Vapor Deposition, Plasma Enhanced Chemical Vapor Deposition and other Chemical Vapor Deposition methods used in semiconductor fabrication processes.

In an integrated circuit process, the formation of polysilicon is very important, especially when the polysilicon is to be used to form a gate of a Metal Oxide Semiconductor (MOS) device, or to be used in a polysilicon intra-connection structure. Generally, when depositing polysilicon using a Chemical Vapor Deposition method, in order to decrease the resistivity of the polysilicon, impurity ions are implanted in a polysilicon layer to increase the conductivity of the polysilicon. Polysilicon doping during a reaction for Chemical Vapor Deposition is one of the commonly used methods at present, such as, for example, a method for fabricating with N-type doped polysilicon as provided in Chinese Patent Application CN01129599.

The process of depositing a polysilicon layer using Chemical Vapor Deposition is generally carried out in a chamber of a Chemical Vapor Deposition apparatus. FIG. 1 shows a process flow of depositing a polysilicon layer using Chemical Vapor Deposition and cleaning the chamber in the prior art.

The above process will be described in detail with reference to FIG. 1. In the prior art, before carrying out the process of depositing a polysilicon layer on a wafer using Chemical Vapor Deposition, referring to step S100, a layer of polysilicon is usually provided in the interior of the chamber of the Chemical Vapor Deposition apparatus. This layer of polysilicon is generally intrinsic polysilicon, such that the environment in the chamber may be unchanged during the process of depositing doped polysilicon on the surface of the wafer, and the conditions and methods for depositing polysilicon on the surface of the wafer may be improved greatly. Herein the interior of the chamber includes the inner walls of the chamber and various components in the chamber.

Then, referring to step S101, the process of depositing a polysilicon layer on the surface of the wafer is carried out using Chemical Vapor Deposition. Generally, a polysilicon layer deposited on a surface of a wafer during a semiconductor fabrication process is a polysilicon layer doped with ions. During the process of depositing the doped polysilicon layer, a layer of doped polysilicon may be also deposited on the interior of the chamber. Moreover, impurities may be produced as reaction products in the chamber during the process of Chemical Vapor Deposition, which may affect the quality of a polysilicon layer deposited in the next Chemical Vapor Deposition. Therefore, referring to step S102, after every batch of wafers has been processed, the chamber needs to be cleaned in a simple way, for example by introducing and ionizing a gas such as NF₃ or the like to form fluoride ions so as to react with the doped and intrinsic polysilicon in the chamber, thereby removing the polysilicon layer and impurity reaction products on the interior of the chamber.

Thereafter, referring to step S103, a layer of intrinsic polysilicon is deposited on the interior of the chamber again, so as to start the Chemical Vapor Deposition of doped polysilicon for the next batch of wafers. Usually, the process of removing polysilicon on the interior of a chamber of a Chemical Vapor Deposition apparatus and the process of depositing a layer of polysilicon on the interior of the chamber again are called a chamber cleaning process collectively.

The polysilicon layer deposited on the inner walls of a chamber in a chamber cleaning process is generally an intrinsic polysilicon layer. As a result, it is found that after a certain number of wafers have been processed, the resistance value of a doped polysilicon layer deposited on a surface of a wafer after a cleaning process in the prior art may increase. Investigations show that this is due to the fact that a large number of cleaning agent ions, e.g., fluoride ions are absorbed by the inner walls of the chamber and other components in the chamber after many cleaning processes in the chamber, and such cleaning agent ions may react with the ions doped in the process of depositing doped polysilicon on the surface of the wafer, resulting in a reduced amount of doped constituents that are deposited on the surface of the wafer and an increased resistance value of the wafer. As a result, the wafer may be wasted and the yield rate may be decreased.

### SUMMARY OF THE INVENTION

A problem to be solved by the present invention is that in the case that a chamber of a Chemical Vapor Deposition apparatus is cleaned through a chamber cleaning process in the prior art, after a number of polysilicon deposition and chamber cleaning processes have been carried out, the resistance value of a doped polysilicon layer deposited on a surface of a wafer may increase.

To solve the above problem, an embodiment of the present invention provides a process for cleaning a chamber in a Chemical Vapor Deposition apparatus, including removing a polysilicon layer formed on the interior of the chamber after a doped polysilicon layer has been deposited on a wafer through Chemical Vapor Deposition, and depositing a doped polysilicon layer on the interior of the chamber.

Preferably, another embodiment of the present invention provides a process for cleaning a chamber in a Chemical Vapor Deposition apparatus, including removing a polysilicon layer formed on the interior of the chamber after a doped polysilicon layer has been deposited on a wafer through Chemical Vapor Deposition, depositing an intrinsic polysilicon layer on the interior of the chamber, and depositing a doped polysilicon layer over the intrinsic polysilicon layer on the interior of the chamber.

Preferably, a thickness ratio of the intrinsic polysilicon layer to the doped polysilicon layer deposited on the interior of the chamber is 1:2 to 1:4.

Preferably, another embodiment of the present invention provides a process for cleaning a chamber in a Chemical Vapor Deposition apparatus, including removing a polysilicon layer formed on the interior of the chamber after a doped polysilicon layer has been deposited on a wafer through Chemical Vapor Deposition, and performing a process of depositing an intrinsic polysilicon layer and a doped polysilicon layer alternately on the interior of the chamber more than one time.

Preferably, a thickness ratio of the intrinsic polysilicon layer to the doped polysilicon layer deposited alternately at the interior of the chamber is 1:2 to 1:4.

Preferably, the doped polysilicon layer is N-type doped or P-type doped.

Compared with the prior art, the embodiments of the present invention are advantageous for the following reasons:

First, in a process for cleaning a chamber in a Chemical Vapor Deposition apparatus according to an embodiment of the present invention, after a polysilicon layer, formed on the interior of the chamber after a doped polysilicon layer has been deposited on a wafer through Chemical Vapor Deposition, has been removed, a doped polysilicon layer is deposited on the inner walls and other components exposed in the chamber such that doped ions can be absorbed sufficiently by the interior of the chamber, and ions doped in a process of depositing a doped polysilicon layer on a surface of a wafer can be prevented from being absorbed by the inner walls of the chamber and the other components in the chamber, resulting in stable doped constituents and resistance value of the doped polysilicon layer deposited on the surface of the wafer.

Second, according to another embodiment of the present invention, after a polysilicon layer, formed on the interior of the chamber after a doped polysilicon layer has been deposited on a wafer through Chemical Vapor Deposition, has been removed, an intrinsic polysilicon layer is first deposited on the interior of the chamber and then a doped polysilicon layer is deposited over the intrinsic polysilicon layer on the interior of the chamber. Due to such a compact intrinsic polysilicon layer deposited intermediately, there may be a balanced ratio of the doped polysilicon layer to the undoped polysilicon layer, such that a dopant gas may be unabsorbable by the inner walls of the chamber and the other components in the chamber when depositing a polysilicon layer on a surface of a wafer, preventing the polysilicon layer on the interior of the chamber from absorbing the dopant gas and avoiding the result that the wafer may be doped insufficiently.

Third, according to another embodiment of the present invention, after a polysilicon layer, formed on the interior of the chamber after a doped polysilicon layer has been deposited on a wafer through Chemical Vapor Deposition, has been removed, a process of depositing an intrinsic polysilicon layer and a doped polysilicon layer alternately on the interior of the chamber is performed more than one time. By depositing an intrinsic polysilicon layer and a doped polysilicon layer repeatedly, a compact polysilicon layer with a balanced doping ratio is formed on the inner walls of the chamber, such that a dopant gas may be more unabsorbable by the inner walls of the chamber and the other components in the chamber through such a coating.

### BRIEF DESCRIPTION OF THE DRAWINGS

FIG. 1 shows a process flow of Chemical Vapor Deposition of a polysilicon layer and cleaning of a chamber in the prior art;

FIG. 2 is a flowchart illustrating a process according to a first embodiment of the present invention;

FIG. 3 is a flowchart illustrating a process according to a second embodiment of the present invention;

FIG. 4 is a flowchart illustrating a process according to a three embodiment of the present invention;

FIG. 5 shows the resistance values of doped polysilicon layers deposited on the surfaces of wafers after the interior of a chamber has been cleaned through a process in the prior art and through a process according to an embodiment of the present invention;

FIG. 6 shows the resistance values of doped polysilicon layers deposited on the surfaces of a first, second and third wafers in a chamber each time the chamber has been cleaned through a cleaning process in the prior art and through a cleaning process according to an embodiment of the present invention.

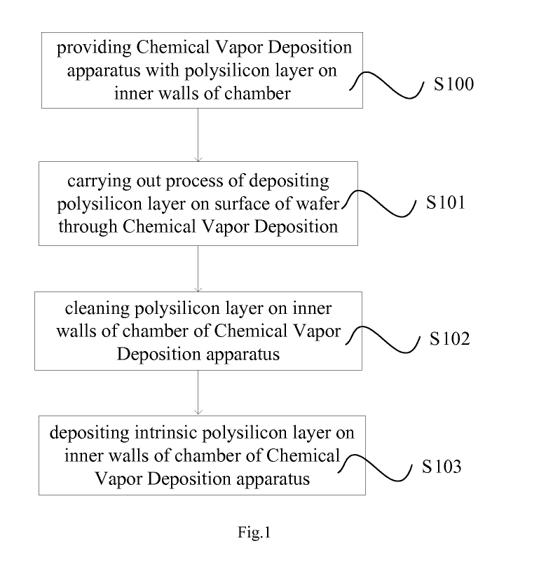

### DETAILED DESCRIPTION OF THE INVENTION

The present invention will be described in detail with reference to the accompanying drawings and the embodiments. The embodiments of the present invention apply to various Chemical Vapor Deposition apparatuses for polysilicon layer deposition to improve the process for cleaning the interior of a chamber of a Chemical Vapor Deposition apparatus during a process for Chemical Vapor Deposition of a polysilicon layer.

### First Embodiment

The first embodiment of the present invention provides a process for cleaning a chamber in a Chemical Vapor Deposition apparatus. The process includes removing a polysilicon layer formed on the interior of the chamber after a doped polysilicon layer has been deposited on a wafer through Chemical Vapor Deposition, and depositing a doped polysilicon layer on the interior of the chamber.

Prior to the process of depositing a doped polysilicon layer on the surface of the wafer using a Chemical Vapor Deposition apparatus, a polysilicon layer has already been deposited on the interior of the chamber of the Chemical Vapor Deposition apparatus, which is generally an intrinsic polysilicon layer in the prior art. Investigations show that such an intrinsic polysilicon layer on the inner walls of the chamber may absorb doped ions in the chamber when doped polysilicon is deposited on a surface of a wafer normally, resulting in a reduced amount of doped ions in the doped polysilicon layer that can be deposited on the surface of the wafer and thus an increased resistance value of the doped polysilicon layer on the surface of the wafer.

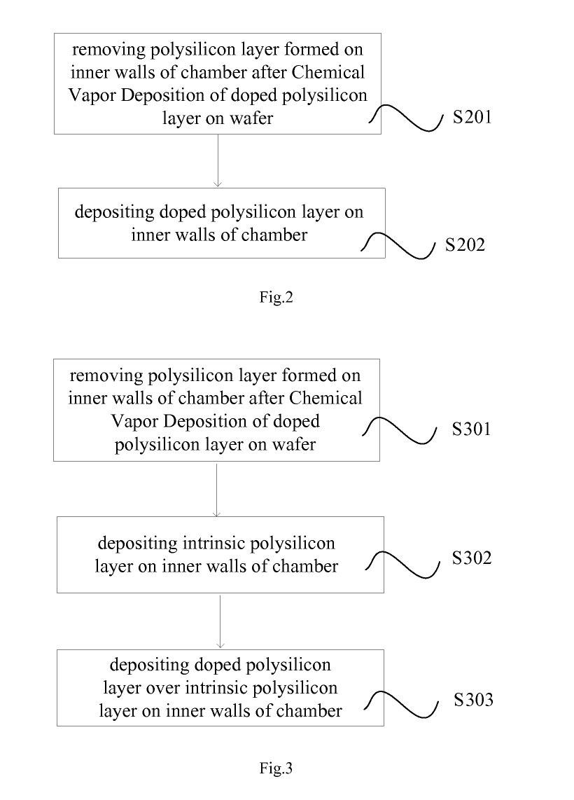

In view of the above, the first embodiment of the present invention provides a process for cleaning a chamber in a Chemical Vapor Deposition apparatus, as shown in FIG. 2 which is a flowchart. First, referring to step S201, a gas such as NF₃ or the like is introduced into the chamber after a doped polysilicon layer has been deposited on a surface of a wafer, so as to remove a polysilicon layer on the interior of the chamber. At this point, the polysilicon layer on the interior of the chamber includes the doped polysilicon layer deposited on the interior of the chamber during the process of depositing the doped polysilicon layer on the surface of the wafer and the intrinsic or doped polysilicon layer deposited on the interior of the chamber before the doped polysilicon layer is deposited on the surface of the wafer. The process of removing the polysilicon layer on the interior of the chamber is not limited to the one described in the present invention, and may be any of the processes in the prior art.

Thereafter, referring to step S202, a doped polysilicon layer is deposited on the interior of the chamber. The process for depositing a doped polysilicon layer may be any process for depositing a doped polysilicon layer in the prior art. The embodiment of the invention provides a specific process in which a doped polysilicon layer of 0.8 μm to 0.9 μm in thickness is deposited at 400° C. to 700° C. under a condition that a gas SiH₄ in 80 sccm to 100 sccm, a gas PH₃ in 30 sccm to 60 sccm, an auxiliary gas N₂, Ar or the like in 9000 sccm to 10000 sccm are introduced into the chamber.

In this embodiment, the doped polysilicon layer may be N-type doped or P-type doped, and the dopant may be doped nitrogen, phosphorus, arsenic ions, or the like, for example.

Afterwards, a doped polysilicon layer may be deposited on the surface of the wafer through a prior art process. Since the polysilicon layer deposited on the interior of the chamber is also a doped polysilicon layer, the doped ions in the environment may not be absorbed by the interior of the chamber during the process of depositing the doped polysilicon layer on the surface of the wafer, such that the resistance value may not increase.

### Second Embodiment

Another embodiment of the present invention provides a process for cleaning a chamber in a Chemical Vapor Deposition apparatus. The process includes removing a polysilicon layer formed on the interior of the chamber after a doped polysilicon layer has been deposited on a wafer through Chemical Vapor Deposition, depositing an intrinsic polysilicon layer on the interior of the chamber, and depositing a doped polysilicon layer over the intrinsic polysilicon layer on the interior of the chamber.

Referring to FIG. 3, as shown at step S301, a polysilicon layer formed on the interior of the chamber after a doped polysilicon layer has been deposited on a wafer through Chemical Vapor Deposition is removed, wherein the process of removing the polysilicon layer has been described with reference to the first embodiment.

Thereafter, as shown at step S302, an intrinsic polysilicon layer is deposited on the interior of the chamber, wherein the process of depositing an intrinsic polysilicon layer may be any of the existing processes well known to those skilled in the art.

Finally, as shown at step S303, a doped polysilicon layer is deposited over the intrinsic polysilicon layer, wherein the process of depositing a doped polysilicon layer has also been described with reference to the first embodiment.

In general, a thickness ratio of the intrinsic polysilicon layer to the doped polysilicon layer deposited on the interior of the chamber is 1:2 to 1:4 in this embodiment of the present invention, so as to ensure that enough ions can be doped in the polysilicon layer on the interior of the chamber when a doped polysilicon layer is deposited on the surface of the wafer, and thus avoiding the doped ions in the environment from being absorbed any more. In addition, to ensure the environment in the chamber during the process of depositing doped polysilicon on the surface of the wafer, a sum of the thickness of the intrinsic polysilicon layer and the doped polysilicon layer deposited on the interior of the chamber may be 0.8 μm to 0.9 μm.

As in the first embodiment, the doped polysilicon layer may be N-type doped or P-type doped, and the dopant may be doped nitrogen, phosphorus, arsenic ions, or the like, for example, in this embodiment.

### Third Embodiment

Another embodiment of the present invention provides a process for cleaning a chamber in a Chemical Vapor Deposition apparatus. The process includes removing a polysilicon layer formed on the interior of the chamber after a doped polysilicon layer has been deposited on a wafer through Chemical Vapor Deposition, and performing a process of depositing an intrinsic polysilicon layer and a doped polysilicon layer alternately on the interior of the chamber more than one time.

Preferably, the process of depositing an intrinsic polysilicon layer and a doped polysilicon layer alternately on the interior of the chamber is performed 3-4 times, wherein each alternation means a process of depositing both an intrinsic polysilicon layer and a doped polysilicon layer. By depositing an intrinsic polysilicon layer and a doped polysilicon layer repeatedly, a compact polysilicon layer with a balanced doping ratio is formed on the inner walls of the chamber, such that a dopant gas may be unabsorbable by the inner walls of the chamber and the other components in the chamber during a process of depositing a doped polysilicon layer on a surface of a wafer.

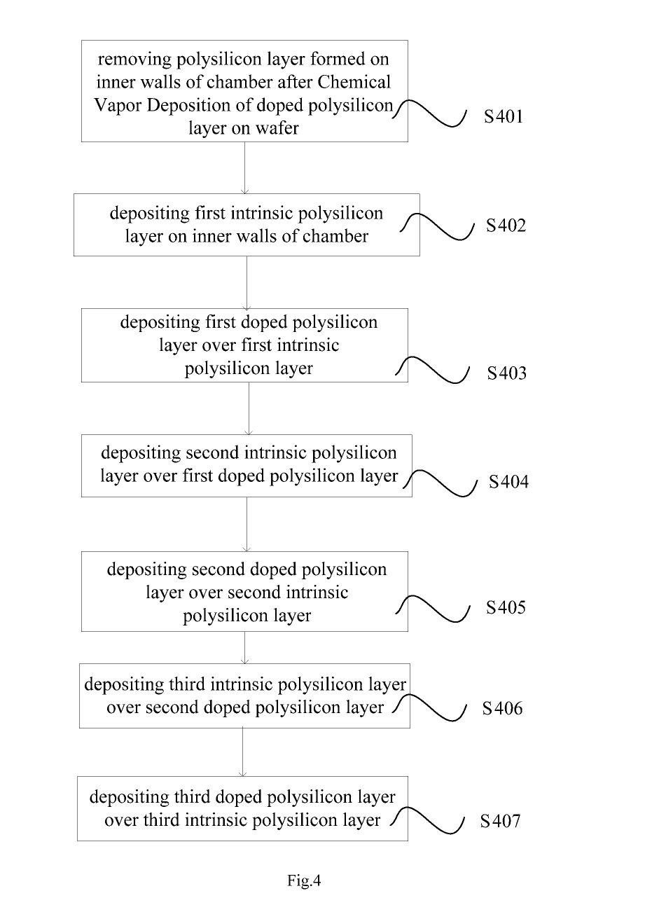

Referring to FIG. 4, there is shown a flowchart of depositing an intrinsic polysilicon layer and a doped polysilicon layer alternately on the interior of the chamber 3 times. As shown at step S401, a polysilicon layer formed on the interior of the chamber after a doped polysilicon layer has been deposited on a wafer through Chemical Vapor Deposition is removed, wherein the process of removing the polysilicon layer has been described with reference to the first embodiment.

Thereafter, as shown at step S402, a first intrinsic polysilicon layer is deposited on the interior of the chamber, wherein the process of depositing a first intrinsic polysilicon layer may be any of the existing processes well known to those skilled in the art. Then, as shown at step S403, a first doped polysilicon layer is deposited over the first intrinsic polysilicon layer. Then, a second intrinsic polysilicon layer is deposited over the first doped polysilicon layer (S404). Then, a second doped polysilicon layer is deposited over the second intrinsic polysilicon layer (S405). Then, a third intrinsic polysilicon layer is deposited over the second doped polysilicon layer (S406). Finally, a third doped polysilicon layer is deposited over the third intrinsic polysilicon layer (S407).

The processes of depositing the first intrinsic polysilicon layer, the second intrinsic polysilicon layer and the third intrinsic polysilicon layer in this embodiment of the invention may be the existing processes well known to those skilled in the art. For the convenience of controlling the processes during the formation, the conditions of the processes of depositing the first intrinsic polysilicon layer, the second intrinsic polysilicon layer and the third intrinsic polysilicon layer are preferably exactly the same. The processes of depositing the first to third doped polysilicon layers may be the same as that described with reference to the first embodiment.

As in the second embodiment, to ensure the environment in the chamber during the process of depositing doped polysilicon on the surface of the wafer, a sum of the thickness of the intrinsic polysilicon layers and the doped polysilicon layers deposited on the interior of the chamber may be 0.8 μm to 0.9 μm. In this embodiment, a ratio of a sum of the thickness of the intrinsic polysilicon layers to a sum of the thickness of the doped polysilicon layers, deposited alternately on the interior of the chamber, is 1:2 to 1:4. Namely, a ratio of a sum of the thickness of the first intrinsic polysilicon layer, the second intrinsic polysilicon layer and the third intrinsic polysilicon layer deposited on the interior of the chamber to a sum of the thickness of the first doped polysilicon layer, the second doped polysilicon layer and the third doped polysilicon layer is 1:2 to 1:4.

In this embodiment, the thickness of the intrinsic polysilicon layer and the doped polysilicon layer deposited in each alternation may be adjusted according to the specific conditions of the process. Preferably, a thickness ratio of the intrinsic polysilicon layer to the doped polysilicon layer deposited in each alternation is 1:2 to 1:4. Namely, it is preferable that the thickness ratio of the first intrinsic polysilicon layer to the first doped polysilicon layer is 1:2 to 1:4, the thickness ratio of the second intrinsic polysilicon layer to the second doped polysilicon layer is 1:2 to 1:4, and the thickness ratio of the third intrinsic polysilicon layer to the third doped polysilicon layer is 1:2 to 1:4.

In this embodiment, the first to third doped polysilicon layers may be N-type doped or P-type doped, and the types of doping for all the doped polysilicon layers in the same process of depositing these doped polysilicon layers at the interior of the chamber are the same.

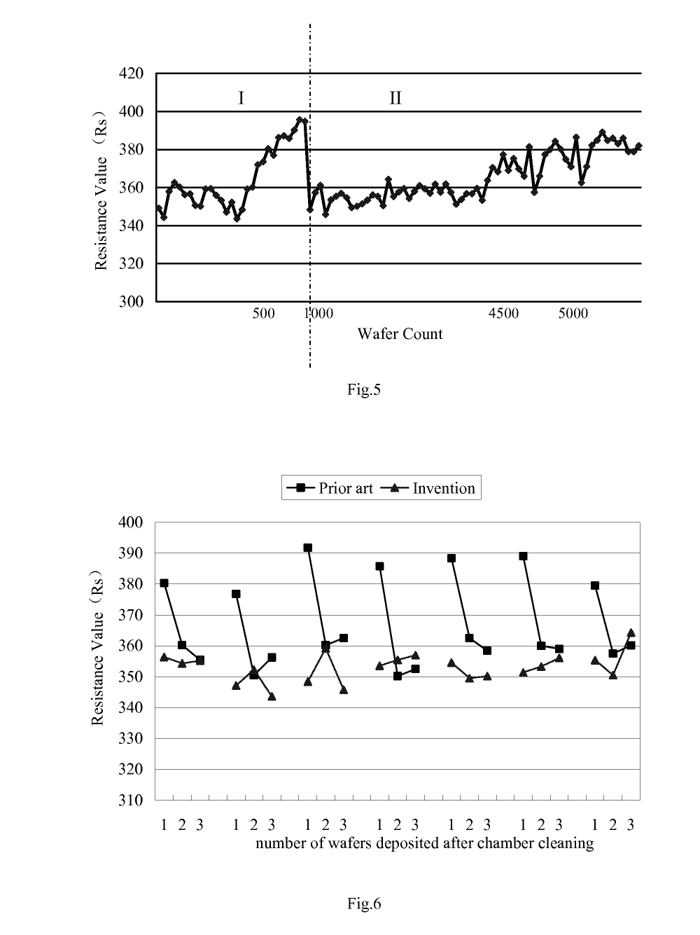

Referring to FIG. 5, a dashed line divides the figure into part I and part II. Part I indicates the resistance values of doped polysilicon layers deposited on the surfaces of wafers after the interior of a chamber has been cleaned through a process in the prior art. As can be seen, the resistance value of a polysilicon layer deposited on a surface of a wafer becomes significantly high after 500 wafers have been processed. Part II indicates the resistance values of doped polysilicon layers deposited on the surfaces of wafers after the interior of the chamber has been cleaned through a process according to an embodiment of the present invention, wherein the provision of the data is started at the 1000^{th} wafer, and the resistance values of the doped polysilicon layers deposited on the surfaces of the first 1000 wafers are almost constant. It can be seen from part II of FIG. 5, after the interior of the chamber has been cleaned through a process according to the embodiment, the resistance value of a doped polysilicon layer deposited on a surface of a wafer begins to increase after 4500 wafers have been deposited with a doped polysilicon layer in the chamber. Furthermore, deposition of 4500 wafers will have approached the expiration of the lifetime of the inner walls of the chamber and the other components in the chamber, where the apparatus needs to be replaced or disassembled for thorough cleaning.

Referring to FIG. 6, there is shown the resistance values of doped polysilicon layers deposited on the surfaces of first, second and third wafers in a chamber each time the chamber has been cleaned through a cleaning process in the prior art and through a cleaning process according to an embodiment of the present invention. As can be seen, after the chamber has been cleaned through a cleaning process in the prior art, the resistance value of the doped polysilicon layer deposited on the surface of the first wafer is much higher than that of the doped polysilicon layer deposited on the surface of the third wafer, while after the chamber has been cleaned through a cleaning process according to the present invention, the resistance value of the doped polysilicon layer deposited on the surface of the first wafer is not very different from that of the doped polysilicon layers deposited on the surfaces of the second and third wafers.

While the preferred embodiments of the present invention have been described as above, it shall be appreciated that the scope of the present invention shall not be limited thereto, and those skilled in the art can make various variations and modifications to the embodiments without departing from the scope of the present invention. Thus, it is intended that all such variations and modifications shall fall within the scope of the present invention as solely defined in the claims thereof

What is claimed is:

1. A process for cleaning a chamber in a Chemical Vapor Deposition apparatus, comprising: removing a polysilicon layer formed on an interior of the chamber after a doped polysilicon layer has been deposited on a wafer through Chemical Vapor Deposition, and depositing a doped polysilicon layer on the interior of the chamber.

2. The process according to claim 1, wherein the thickness of the doped polysilicon layer is 0.8 μm to 0.9 μm.

3. The process according to claim 1, wherein the doped polysilicon layer is N-type doped or P-type doped.

4. A process for cleaning a chamber in a Chemical Vapor Deposition apparatus, comprising:
removing a polysilicon layer formed on an interior of the chamber after a doped polysilicon layer has been deposited on a wafer through Chemical Vapor Deposition, depositing an intrinsic polysilicon layer on the interior of the chamber, and depositing a doped polysilicon layer over the intrinsic polysilicon layer on the interior of the chamber.

5. The process according to claim 4, wherein a thickness ratio of the intrinsic polysilicon layer to the doped polysilicon layer deposited on the interior of the chamber is 1:2 to 1:4.

6. The process according to claim 4, wherein a total thickness of the intrinsic polysilicon layer and the doped polysilicon layer deposited on the interior of the chamber is 0.8 μm to 0.9 μm.

7. The process according to claim 4, wherein the doped polysilicon layer is N-type doped or P-type doped.

8. A process for cleaning a chamber in a Chemical Vapor Deposition apparatus, comprising: removing a polysilicon layer formed on an interior of the chamber after a doped polysilicon layer has been deposited on a wafer through Chemical Vapor Deposition, and performing a process of depositing an intrinsic polysilicon layer and a doped polysilicon layer alternately on the interior of the chamber more than one time.

9. The process according to claim 8, wherein a ratio of a sum of the thickness of the intrinsic polysilicon layers to a sum of the thickness of the doped polysilicon layers, deposited alternately on the interior of the chamber, is 1:2 to 1:4.

10. The process according to claim 8, wherein the process of depositing an intrinsic polysilicon layer and a doped polysilicon layer alternately on the interior of the chamber is performed 3-4 times.

11. The process according to claim 8, wherein a sum of the thickness of the intrinsic polysilicon layers and the doped polysilicon layers deposited alternately at the interior of the chamber is 0.8 μm to 0.9 μm.

12. The process according to claim 8, wherein the doped polysilicon layer is N-type doped or P-type doped.
